(19) United States
(12) Patent Application Publication
(10) Pub. No.: US 2011/0279387 A1
(43) Pub. Date: Nov. 17, 2011

(54) Transperent Conductive Substrate and Method of Manufacturing the same Touch Screen Using the Same

(75) Inventors: Woon Chun Kim, Suwon (KR); Yong Soo Oh, Seongnam-si (KR); Jong Young Lee, Suwon (KR); Yong Hyun Jin, Seoul (KR)

(73) Assignee: SAMSUNG ELECTRO-MECHANICS CO., LTD., Gyeonggi-do (KR)

(21) Appl. No.: 12/881,451

(22) Filed: Sep. 14, 2010

(30) Foreign Application Priority Data
May 13, 2010 (KR) 10-2010-0044986

(51) Int. Cl. G06F 3/041; B05D 5/12; H05K 3/06; B32B 3/10

(52) U.S. Cl. 345/173; 428/203; 428/205; 427/108; 216/13

(57) ABSTRACT

Disclosed herein are a transparent conductive substrate and a method of manufacturing the same, and a touch screen using the same. The transparent conductive substrate includes a transparent substrate, a transparent electrode that is formed and patterned on the transparent substrate, and a primer that is formed between the transparent substrate and the transparent electrode and is patterned to have a pattern corresponding to the transparent electrode. The transparent electrode is easily patterned by previously patterning the primer to correspond to the transparent electrode and residues do not remain on the transparent substrate.

### CROSS REFERENCE TO RELATED APPLICATION

This application claims the benefit of Korean Patent Application No. 10-2010-0044986, filed on May 13, 2010, entitled “Transparent Conductive Substrate And Method Of Manufacturing The Same And Touch Screen Using The Same”, which is hereby incorporated by reference in its entirety into this application.

### BACKGROUND OF THE INVENTION

1. Technical Field

The present invention relates to a transparent conductive substrate and a method of manufacturing the same, and a touch screen using the same.

2. Description of the Related Art

With the continuous development in the electronic technology and the information technology fields, the relative importance of electronic devices is constantly increasing in everyday life, including a work environment. In particular, as electronic technology continuously develops, touch screens are used in portable devices that are recently reduced in size and thickness.

Touch screens, devices generally installed in display devices to detect positions on the screen touched by a user and control electronic devices, using information on the detected contact position as input information, in addition to controlling the screen of the display, have various advantages of being simply operated with little malfunction in a small space and very compatible with IT devices.

Meanwhile, the touch screen is classifiable as a resistive type, a capacitive type, an electromagnetic type, a surface acoustic wave (SAW) type, an infrared type, and so on. Among others, resistive and capacitive types are prevalently used in consideration of the functions and costs.

In particular, in the cases of the resistive and capacitive touch screens, one sheet or two sheets of transparent conductive substrates are used. However, a transparent substrate and an indium tin oxide (ITO) electrode of the transparent conductive substrate have different physical properties to have weak adhesion therebetween, such that the ITO electrode is separate from the touch screen. In order to solve this problem, a primer is formed between the transparent substrate and the ITO electrode of the transparent conductive substrate so as to improve adhesion therebetween.

FIGS. 1 to 3 are process cross-sectional views explaining a method of manufacturing a transparent conductive substrate 10 included in a touch screen according to the prior art. Hereinafter, the transparent conductive substrate 10 according to the prior art will be described with reference to these figures.

As shown in FIG. 1, first, a primer 12 is formed over a transparent substrate 11 so as to improve adhesion with an ITO electrode 13.

Next, as shown in FIG. 2, the ITO electrode 13 is formed over the primer 12 by a sputtering method.

Next, as shown in FIG. 3, the ITO electrode 13 is patterned by an etching method.

The transparent conductive substrate 10 shown in FIG. 3 is manufactured in the prior art according to the manufacturing processes described above.

However, even though the transparent conductive substrate 10 according to the prior art is formed with the primer 12 to improve the adhesion between the transparent substrate 11 and the ITO electrode 13, the primer 12 is formed over the transparent substrate 11 does not have a difference in surface characteristics, such that it is difficult to pattern the ITO electrode 13. More specifically, a portion to be removed when patterning the ITO electrode 13 remains on the transparent substrate 11 due to the adhesion of the primer 12, such that a residue 14 remains. Such a residue 14 becomes an obstacle in processing a signal from the ITO electrode 13 and causes a malfunction of a touch screen.

### SUMMARY OF THE INVENTION

The present invention has been made in an effort to provide a transparent conductive substrate that easily patterns a transparent electrode and prevents malfunction of a touch screen, etc. by completely removing residues, a method of manufacturing the same, and a touch screen using the same.

A transparent conductive substrate according to a preferred embodiment of the present invention includes: a transparent substrate; a transparent electrode that is formed and patterned on the transparent substrate; and a primer that is formed between the transparent substrate and the transparent electrode and is patterned to have a pattern corresponding to the transparent electrode.

Herein, the transparent electrode is made of a conductive polymer.

Further, the primer is made of polyurethane or polyacrylate.

A touch screen according to a preferred embodiment of the present invention includes: two sheets of transparent conductive substrates that are opposite to each other and include: a transparent substrate, a transparent electrode that is formed and patterned on the transparent substrate to sense input signals, and a primer that is formed between the transparent substrate and the transparent electrode and is patterned to have a pattern corresponding to the transparent electrode; and an adhesive layer that is formed between the two sheets of transparent conductive substrates.

Herein, the transparent electrode is made of a conductive polymer.

Further, the primer is made of polyurethane or polyacrylate.

A method of manufacturing a transparent conductive substrate according to a preferred embodiment includes: (A) patterning and forming a primer on a transparent substrate; and (B) forming a transparent electrode on the primer to have a pattern corresponding to the primer.

Herein, the transparent electrode is made of a conductive polymer.

Further, the primer is made of polyurethane or polyacrylate.

Further, at step (A), the primer is patterned and formed by a printing method, a coating method, or an etching method.

Further, at step (B), the transparent electrode is formed by a printing method or a coating method.

Step (B) further includes: (B1) preparing a screen having an opening at a position corresponding to the pattern of the primer; and (B2) forming a transparent electrode on the primer to have a pattern corresponding to the primer by printing a conductive polymer through the opening of the screen.

Step (B) further includes: (B1) forming a transparent electrode over the transparent substrate on which the primer is formed; and (B2) patterning the transparent electrode by an etching method or a laser method so that the transparent electrode has a pattern corresponding to the primer.

### BRIEF DESCRIPTION OF THE DRAWINGS

FIGS. 1 to 3 are process cross-sectional views explaining a method of manufacturing a transparent conductive substrate included in a touch screen according to the prior art;

FIG. 4 is a cross-sectional view of a transparent conductive substrate according to a preferred embodiment of the present invention;

FIG. 5 is a cross-sectional view of a touch screen that includes the transparent conductive substrate of FIG. 4;

FIGS. 6 to 8 are process cross-sectional views explaining a method of manufacturing a transparent conductive substrate according to a first preferred embodiment of the present invention; and

FIGS. 9 to 11 are process cross-sectional views explaining a method of manufacturing a transparent conductive substrate according to a second preferred embodiment of the present invention.

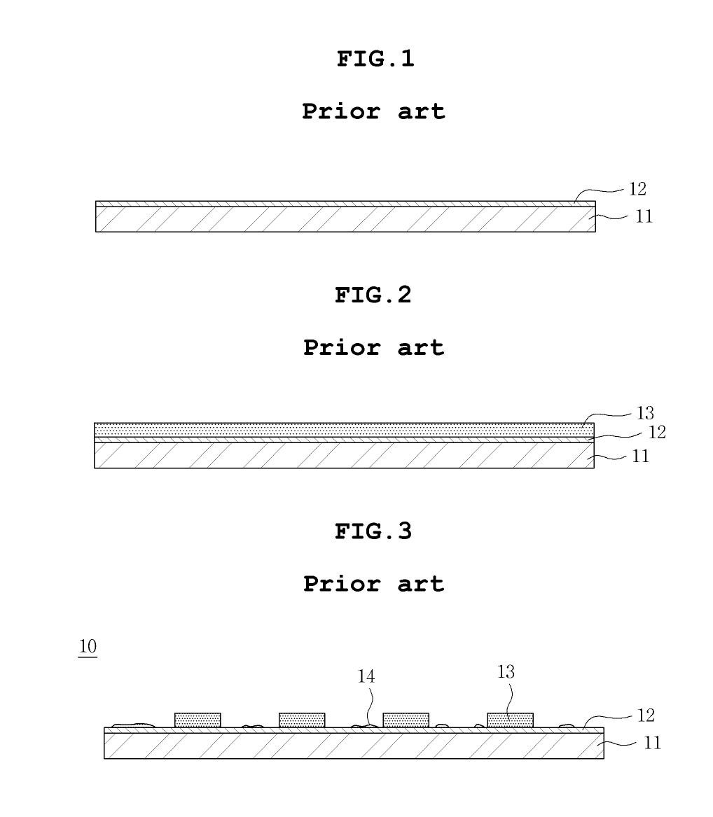

### DESCRIPTION OF THE PREFERRED EMBODIMENTS

Various features and advantages of the present invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

Various objects, advantages and features of the invention will become apparent from the following description of embodiments with reference to the accompanying drawings. In the specification, in adding reference numerals to components throughout the drawings, it is to be noted that like reference numerals designate like components even though components are shown in different drawings. Further, terms used in the specification, ‘first’, ‘second’, etc. can be used to describe various components, but the components are not to be construed as being limited to the terms. The terms are only used to differentiate one component from other components. Further, when it is determined that the detailed description of the known art related to the present invention may obscure the gist of the present invention, the detailed description thereof will be omitted.

Hereinafter, preferred embodiments of the present invention will be described in detail with reference to the accompanying drawings.

Meanwhile, although the present invention will describe a touch screen to which a transparent conductive substrate is applied by way of example, the present invention is not limited thereto but a transparent conductive substrate according to the present embodiment may also be applied to a solar cell, a display field, or the like.

Structure of Transparent Conductive Substrate

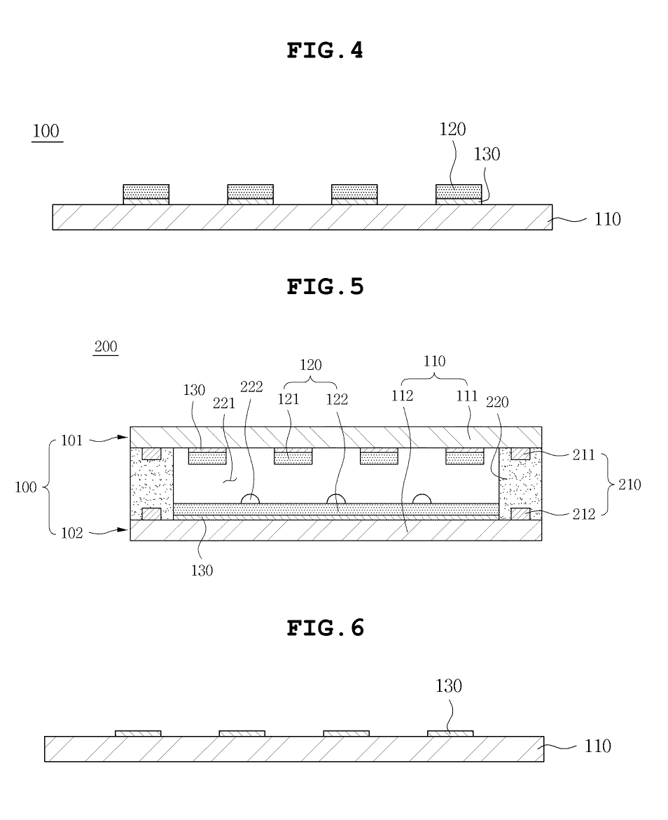

FIG. 4 is a cross-sectional view of a transparent conductive substrate 100 according to a preferred embodiment of the present invention. Hereinafter, the transparent conductive substrate 100 according to the present embodiment will be described with reference to the figure.

As shown in FIG. 4, the transparent conductive substrate 100 according to the present embodiment includes a transparent substrate 110, a transparent electrode 120, and a primer 130, and has a pattern in which the transparent electrode 120 corresponds to the primer 130.

The transparent substrate 110 is a member that provides a space where the transparent electrode 120 is formed.

Herein, it is preferable that the transparent substrate 110 is made of a material having large durability so that other components of the transparent conductive substrate 100 can be sufficiently protected from external force. Further, it is preferable that the transparent substrate 110 is made of a transparent material so that an image from a display (not shown) can be clearly transferred to a user. The transparent substrate 110 may, for example, be made of polyethyleneterephthalate (PET), polycarbonate (PC), polymethylmethacrylate (PMMA), polyethylenenaphthalenedicarboxylate (PEN), polyethersulfone (PES) or cyclic olefin copolymer (COC). Besides, glass or tempered glass that is generally used may also be used.

The transparent electrode 120 is a member that is formed on the transparent substrate 110 to sense various electrical signals.

Herein, when the transparent conductive substrate 100 is used as a touch screen, the transparent electrode 120 can sense a signal generated by an input. In the case of a capacitive touch screen, for example, the transparent electrode 120 measures parasitic capacitance from the input, senses the change in capacitance, and transfers the change to a controller (not shown), and the controller (not shown) recognizes coordinates of the pressed position, thereby implementing desired operation. More specifically, when high frequency is diffused throughout the transparent electrodes 120 by an applied voltage and then an input is generated, a predetermined change occurs in capacitance while the transparent electrodes 120 function as electrodes and the transparent substrates 110 function as dielectrics, and the controller (not shown) can recognize the input position or whether there is an input, by detecting the changed waveform.

Meanwhile, the transparent electrode 120 may be patterned to have a predetermined shape. For example, the transparent electrode 120 may be patterned to have various shapes, such as a rod shape, a tooth shape, a diamond shape, a hexagonal shape, an octagonal shape, a triangular shape or the like. When an X-axis pattern and a Y-axis pattern are formed on one layer, the respective patterns may be connected through a bridge.

In addition, it is preferable that the transparent electrode 120 is made of a transparent material which enables a user to see a display (not shown) well and is made of a material having conductivity. The transparent electrode 120 may, for example, be made of a conductive polymer containing poly-3,4-ethylenedioxythiophene/polystyrenesulfonate (PEDOT/PSS), polyaniline alone or a mixture thereof, or metal oxides, such as indium tin oxide (ITO).

The primer 130 is a member that is formed between the transparent substrate 110 and the transparent electrode 120 to improve adhesion between the transparent substrate 110 and the transparent electrode 120.

Herein, the primer 130 is patterned to correspond to the transparent electrode 120. Therefore, the primer 130 is formed on only the portion where the transparent electrode 120 is formed, such that the upper surface thereof may not be exposed to the outside. In addition, the primer 130, which has excellent adhesion, may use, for example, polyester, polyester fiber, polyacrylate, silicone acrylic resin, methacrylic resin, acrylic resin, melamine resin, polysiloxane resin, or the like.

Meanwhile, even though a thickness of the primer 130 is not specifically limited, but preferably, is 0.005 to 10 μm. If the primer 130 has a thickness of 0.005 μm or less, it is difficult to effectively obtain the adhesion improvement effect, whereas if the primer 130 has a thickness of 10 μm or more, a phenomenon that aggregation of the primer 130 is broken occurs so that the adhesion improvement effect is similarly degraded.

Structure of Touch Screen Using Transparent Conductive Substrate

FIG. 5 is a cross-sectional view of a touch screen 200 that includes the transparent conductive substrate 100 of FIG. 4. Hereinafter, the touch screen 200 according to the present embodiment will be described with reference to the figure.

The resistive touch screen 200 that includes two sheets of transparent conductive substrates 100 will be described in the present embodiment by way of example. However, the present invention is not limited thereto, but may also include a case in which the transparent conductive substrates 100 according to the present embodiment are used in a capacitive touch screen.

As shown in FIG. 5, the touch screen 200 according to the present embodiment may include two sheets of transparent conductive substrates 100 that are opposite to each other, an electrode 210, an adhesive layer 220, and a dot spacer 222.

The transparent conductive substrate 100 includes a first transparent conductive substrate 101 that is formed on an upper part of the touch screen 200 and a second transparent conductive substrate 102 that is formed on the lower part thereof.

Herein, the first transparent conductive substrate 101 is a member that directly receives an input from a specific object, such as a user's body, a stylus pen, or the like. Therefore, it is preferable that a first transparent substrate 111 is made of an elastic material so that it is bent when an input is applied and is returned again to its original position when the input is released. The second transparent conductive substrate 102 is not a member that directly receives an input. Therefore, a second transparent substrate 112 may be made of a rigid material as compared to the first transparent substrate 111.

Meanwhile, the first transparent electrode 121 and the second transparent electrode 122 are formed to be opposite to each other so that they are electrically connected to each other by contacting each other when there is an input. Specifically, when there is an input by a specific object, such as a user's body, a stylus pen, or the like, the first transparent conductive substrate 101 is bent toward the second transparent conductive substrate 102 by pressure of the input and thus the first transparent electrode 121 directly contacts the second transparent electrode 122, such that change in resistance or voltage is generated. Further, a controller (not shown) may recognize pressed coordinates based thereon, thereby making it possible to implement desired operations. At this time, when the first transparent electrode 121 is made of a conductive polymer, the first transparent substrate 111 having large flexibility is more bendable when an input is applied, that is, a radius of curvature becomes small, such that accurate coordinates can be measured.

The electrode 210, which is a member that applies voltage to each transparent electrode 120, is formed on the transparent substrate 110 to be electrically connected to the transparent electrodes 120.

Herein, it is preferable that the electrode 210 is made of a material having excellent electrical conductivity so that a first electrode 211 supplies voltage to the first transparent electrode 121 and a second electrode 212 supplies voltage to the second transparent electrode 122, respectively. For example, the electrode 210 may be made of a material composed of silver (Ag) paste or organic silver. Further, in order to reduce a bezel region, the electrode 210 may be made of a transparent material, such as a conductive polymer or a metal oxide, similar to the transparent electrode 120.

The adhesive layer 220 is a member that is formed between the first transparent conductive substrate 101 and the second transparent conductive substrate 102 to bond the first transparent conductive substrate 101 to the second transparent conductive substrate 102.

Herein, the adhesive layer 220 is formed at the outside between the first transparent conductive substrate 101 and the second transparent conductive substrate 102, wherein an opening 221 that is an air layer may be formed inside the adhesive layer 220. At this time, the reason why the adhesive layer 220 is not formed at the inside between the first transparent conductive substrate 101 and the second transparent conductive substrate 102 is to allow the first transparent electrode 121 to directly contact the second transparent electrode 122 when there is an input. Further, the adhesive layer 220 is formed only at the outside between the first transparent conductive substrate 101 and the second transparent conductive substrate 102, such that the adhesive layer 220 may, for example, be formed of a double-sided adhesive tape (DAT).

Meanwhile, the dot spacer 222 may further be formed on any one of the first transparent electrode 121 and the second transparent electrode 122. The dot spacer 222 relieves the impact generated when the first transparent electrode 121 contacts the second transparent electrode 122 and provides repulsive force so that the first transparent conductive substrate 101 is returned to its original position when an input is released. Further, the dot spacer 222 serves to maintain insulation between the first transparent electrode 121 and the second transparent electrode 122 at normal times so that the first transparent electrode 121 does not contact the second transparent electrode 122 when there is no external pressure.

Meanwhile, in a capacitive touch screen, the adhesive layer (not shown) is formed over the first transparent conductive substrate 101 and the second transparent conductive substrate 102 to maintain insulation between the first transparent electrode 121 and the second transparent electrode 122. The adhesive layer may be made of a transparent material having insulation and adhesion, for example, an optical clear adhesive (OCA).

Method of Manufacturing Transparent Conductive Substrate

FIGS. 6 and 8 are diagrams explaining a method of manufacturing a transparent conductive substrate 100a according to a first preferred embodiment of the present invention. Herein, a method of manufacturing a transparent conductive substrate 100a according to the present embodiment will be described with reference to FIGS. 6 and 8.

As shown in FIG. 6, first, a patterned primer 130 is formed on a transparent substrate 110.

At this time, the primer 130 may be patterned by, for example, a printing method or a coating method, to be formed on the transparent substrate 110. Further, the primer 130 may also be patterned in the manner that the primer 130 is formed over the transparent substrate 110 and then a portion thereof is etched by an etching method.

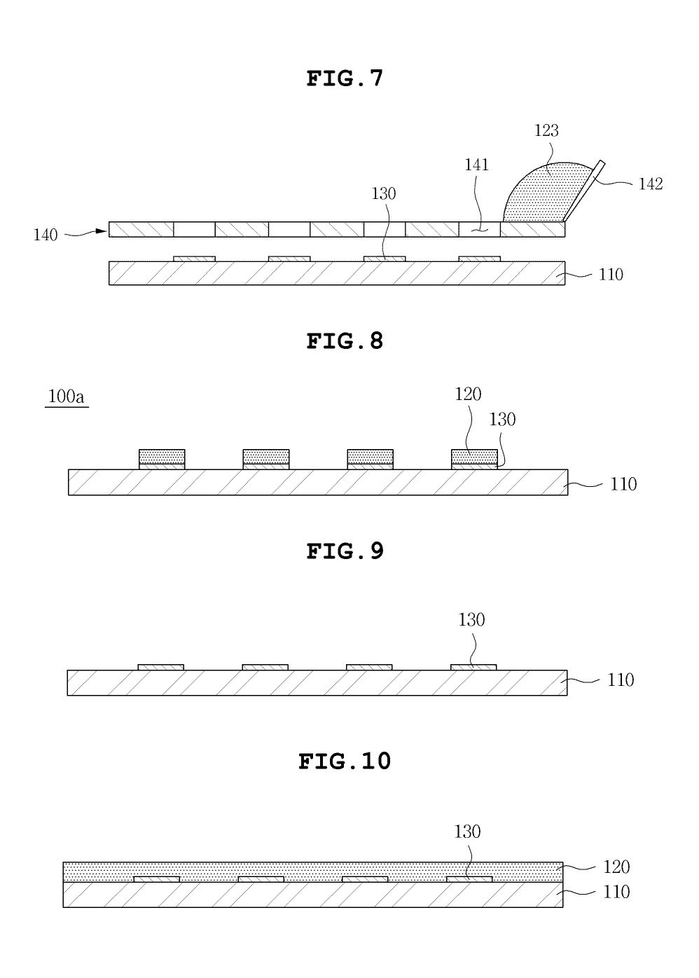

Next, as shown in FIG. 7, a screen 140 formed with an opening 141 is positioned to correspond to the pattern of the primer 130 and a material 123 of a transparent electrode 120 is supplied onto the screen 140.

At this time, the material 123 of the transparent electrode 120, for example, ink paste made of a conductive polymer, is put on the screen 140 in a state in which the screen 140 is tightly pulled by strong tension and then the material 123 of the transparent electrode 120 is pushed out to the surface of the transparent substrate 110 through the opening 141 of the screen 140 to be transferred by pushing down and moving a squeegee 142.

Next, as shown in FIG. 8, the transparent electrode 120 having a pattern corresponding to the primer 130 is formed by removing the screen 140.

At this time, the opening 141 of the screen 140 is formed on the position corresponding to the pattern of the primer 130, such that the transparent electrode 120 transferred through the opening 141 may be positioned only on the position where the primer 130 is formed. In addition, although the material 123 of the transparent electrode 120 is in a liquid phase so as to be diffused onto the transparent substrate 110 on which the primer 130 is not formed, the portion where the primer 130 is not formed has relatively weak adhesion, such that the transparent electrode 120 may be formed only on the portion where the primer 130 is patterned. Further, the diffusion phenomenon of the material 123 of the transparent electrode 120 is prevented and the adhesion between the transparent electrode 120 and the transparent substrate 110 is improved, thereby making it possible to make a line width of the transparent electrode 120 fine.

The transparent conductive substrate 100a according to the preferred first embodiment of the present invention, as shown in FIG. 8, is manufactured by the manufacturing processes as described above.

Meanwhile, even though the present embodiment describes a screen printing method as the method of manufacturing the transparent electrode 120 by way of example, the present invention is not limited thereto but may form the transparent electrode 120 by, for example, a printing method such as an inkjet printing method, a gravure printing method, an offset printing method, or the like, and a coating method.

FIGS. 9 to 11 are diagrams explaining a method of manufacturing a transparent conductive substrate 100b according to a second preferred embodiment of the present invention. Hereinafter, a method of manufacturing a transparent conductive substrate 100b according to the present embodiment will be described with reference to FIGS. 9 to 11. Herein, like reference numerals will designate identical or corresponding components, and a description overlapping with the first embodiment will be omitted.

As shown in FIG. 9, first, a patterned primer 130 is formed on a transparent substrate 110.

Next, as shown in FIG. 10, a transparent electrode 120 is formed over the transparent substrate 110 on which the primer 130 is formed.

At this time, the transparent electrode 120 may be formed over the transparent substrate 110 by, for example, a printing method, a coating method, a sputtering method, or the like. Herein, the primer 130 is in a patterned state, a portion of the transparent electrode 120 may be formed on the primer 130 and the rest thereof may be formed on the transparent substrate 110.

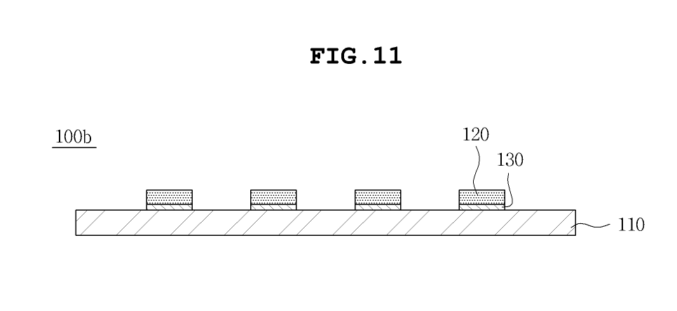

Next, as shown in FIG. 11, the transparent electrode 120 is patterned to have a pattern corresponding to the primer 130 by an etching method or a laser method.

When using an etching method, an etching resist is formed on the pattern portion corresponding to the primer 130 and an etching liquid, such as NaOH, KOH, or the like, is applied on the transparent electrode 120 and then, the etching resist is removed, thereby patterning the transparent electrode 120. When using a laser method, the portion of the transparent electrode 120 not formed on the primer 130 is etched by laser, thereby patterning the transparent electrode 120 to correspond to the primer 130.

Herein, the primer 130 is formed to have a pattern corresponding to the transparent electrode 120, such that the portion on which the primer 130 is not formed has relatively low adhesion, as a result, the portion of the transparent electrode 120 to be removed may be easily etched. Further, residues may not remain on the transparent substrate 110 even without being subject to a separate process.

The transparent conductive substrate 100b according to the preferred second embodiment of the present invention, as shown in FIG. 11, is manufactured by the manufacturing processes as described above.

According to the present invention, the transparent conductive substrate and the method of manufacturing the same, and the touch screen using the same, provides process convenience in patterning the transparent electrode by an etching method or a laser method by patterning the primer to correspond to the transparent electrode, and does not leave residues due to the adhesion of the primer on the portion from which the transparent electrode is to be removed.

In addition, according to the present invention, when the transparent electrode is formed by a printing method or a coating method, the primer is previously patterned to correspond to the transparent electrode, thereby preventing the material of the transparent electrode from being diffused.

In addition, according to the present invention, when the transparent electrode is formed by a printing method or a coating method, the diffusion phenomenon of the material of the transparent electrode is prevented and the adhesion between the transparent electrode and the transparent substrate is improved, thereby making a line width of the transparent electrode fine.

Although the embodiment of the present invention has been disclosed for illustrative purposes, it will be appreciated that a transparent conductive substrate and a method of manufacturing the same, and a touch screen using the same according to the present invention are not limited thereby, and those skilled in the art will appreciate that various modifications, additions and substitutions are possible, without departing from the scope and spirit of the invention.

Accordingly, such modifications, additions and substitutions should also be understood to fall within the scope of the present invention.

What is claimed is:

1. A transparent conductive substrate, comprising:
a transparent substrate;
a transparent electrode that is formed and patterned on the transparent substrate; and
a primer that is formed between the transparent substrate and the transparent electrode and is patterned to have a pattern corresponding to the transparent electrode.

2. The transparent conductive substrate as set forth in claim 1, wherein the transparent electrode is made of a conductive polymer.

3. The transparent conductive substrate as set forth in claim 1, wherein the primer is made of polyurethane or polyacrylate.

4. A touch screen, comprising:
two sheets of transparent conductive substrates that are opposite to each other and include a transparent substrate, a transparent electrode that is formed and patterned on the transparent substrate to sense input signals, and a primer that is formed between the transparent substrate and the transparent electrode and is patterned to have a pattern corresponding to the transparent electrode; and
an adhesive layer that is formed between the two sheets of transparent conductive substrates.

5. The touch screen as set forth in claim 4, wherein the transparent electrode is made of a conductive polymer.

6. The touch screen as set forth in claim 4, wherein the primer is made of polyurethane or polyacrylate.

7. A method of manufacturing a transparent conductive substrate, comprising:
(A) patterning and forming a primer on a transparent substrate; and
(B) forming a transparent electrode on the primer to have a pattern corresponding to the primer.

8. The method of manufacturing a transparent conductive substrate as set forth in claim 7, wherein the transparent electrode includes a conductive polymer.

9. The method of manufacturing a transparent conductive substrate as set forth in claim 7, wherein the primer includes polyurethane or polyacrylate.

10. The method of manufacturing a transparent conductive substrate as set forth in claim 7, wherein at step (A), the primer is patterned and formed by a printing method, a coating method, or an etching method.

11. The method of manufacturing a transparent conductive substrate as set forth in claim 7, wherein at step (B), the transparent electrode is formed by a printing method or a coating method.

12. The method of manufacturing a transparent conductive substrate as set forth in claim 7, wherein step (B) further includes:
(B1) preparing a screen having an opening at a position corresponding to the pattern of the primer; and
(B2) forming a transparent electrode on the primer to have a pattern corresponding to the primer by printing a conductive polymer through the opening of the screen.

13. The method of manufacturing a transparent conductive substrate as set forth in claim 7, wherein step (B) further includes:
(B1) forming a transparent electrode over the transparent substrate on which the primer is formed; and
(B2) patterning the transparent electrode by an etching method or a laser method so that the transparent electrode has a pattern corresponding to the primer.
